(19) United States
(12) Patent Application Publication
(10) Pub. No.: US 2023/0060645 A1
(43) Pub. Date: Mar. 2, 2023

(54) METAL OXIDE THIN FILM TRANSISTOR, AND METHOD FOR PREPARING METAL OXIDE THIN FILM TRANSISTOR AND ARRAY SUBSTRATE

(71) Applicant: BOE Technology Group Co., Ltd., Beijing (CN)

(72) Inventors: Jiayu HE, Beijing (CN); Ce NING, Beijing (CN); Zhengliang LI, Beijing (CN); Hehe HU, Beijing (CN); Jie HUANG, Beijing (CN); Kun ZHAO, Beijing (CN); Nianqi YAO, Beijing (CN)

(73) Assignee: BOE Technology Group Co., Ltd., Beijing (CN)

(21) Appl. No.: 17/800,389

(22) PCT Filed: May 27, 2021
(86) PCT No.: PCT/CN2021/096540

§ 371 Date: Aug. 17, 2022

(30) Foreign Application Priority Data
Jun. 16, 2020 (CN) 202010549104.3

(51) Int. Cl. H01L 29/786; H01L 27/12; H01L 29/24; H01L 29/49; H01L 21/02; H01L 21/443; H01L 29/66

(52) U.S. Cl. CPC H01L 29/7869; H01L 27/1225; H01L 29/24; H01L 29/4908; H01L 29/78696; H01L 21/02164; H01L 21/02271; H01L 21/02565; H01L 21/02631; H01L 21/443; H01L 29/66969; G02F 1/1368

(57) ABSTRACT

A metal oxide thin film transistor is provided and includes a gate, a gate insulating layer, an active layer and a source-drain metal layer stacked on a side of a backplane, the active layer and the gate are provided on both sides of the gate insulating layer, the source-drain metal layer is provided on a side of the active layer away from the backplane, the active layer includes: a first metal oxide semiconductor layer provided on a side of the gate insulating layer away from the gate; a second metal oxide semiconductor layer provided on a surface of the first metal oxide semiconductor layer away from the gate.

### CROSS-REFERENCE TO RELATED APPLICATIONS

The present application is a U.S. National Stage of International Application No. PCT/CN2021/096540, filed on May 27, 2021, which is based upon and claims priority to Chinese Patent Application No. 202010549104.3, entitled “METAL OXIDE THIN FILM TRANSISTOR AND PREPARATION METHOD THEREFOR, AND ARRAY SUBSTRATE”, filed Jun. 16, 2020, the entire content of which is incorporated herein by reference.

### TECHNICAL FIELD

The present disclosure relates to a field of display technology, and more particularly to a metal oxide thin film transistor, a method for preparing metal oxide thin film transistor, and an array substrate.

### BACKGROUND

An oxide thin film transistor has advantages of good uniformity, which brings a good application prospect in high-generation line panel, large-scale display and the like. A BCE (Back-Channel-Etching) type oxide thin film transistor is a commonly used oxide thin film transistor structure, which is usually oxide semiconductor structure with a single layer and high mobility. The BCE type oxide thin film transistor with this structure has defects of low mobility and low stability.

The information disclosed in the Background section above is only for enhancing the understanding of the background of the present disclosure, and thus may include information that does not constitute prior art known to those of ordinary skill in the art.

### SUMMARY

The present disclosure aims to provide a metal oxide thin film transistor, a method for preparing metal oxide thin film transistor, and an array substrate to improve carrier mobility and stability.

To achieve the above-mentioned purpose of the disclosure, the present disclosure adopts the following technical solutions:

According to a first aspect of the present disclosure, a metal oxide thin film transistor is provided, and includes a gate, a gate insulating layer, an active layer and a source-drain metal layer stacked on a side of a backplane, wherein the active layer and the gate are provided on both sides of the gate insulating layer, respectively, and the source-drain metal layer is provided on a side of the active layer away from the backplane, the active layer includes:

a first metal oxide semiconductor layer provided on a side of the gate insulating layer away from the gate; wherein a carrier concentration in the first metal oxide semiconductor layer is greater than 1×10²⁰ cm⁻³, hall mobility of carriers in the first metal oxide semiconductor layer is greater than 20 cm²/(V·s), and a total atomic percentage of indium and zinc in the first metal oxide semiconductor layer is greater than 40%;

a second metal oxide semiconductor layer provided on a surface of the first metal oxide semiconductor layer away from the gate.

In an exemplary embodiment of the present disclosure, the carrier concentration in the first metal oxide semiconductor layer is equal to or less than 1×10²⁰ cm⁻³, and the hall mobility of the carriers in the first metal oxide semiconductor layer is within a range of 25 cm²/(V·s) to 50 cm²/(V·s).

In an exemplary embodiment of the present disclosure, a band gap of material of the second metal oxide semiconductor layer is equal to or greater than 3.0 eV.

In an exemplary embodiment of the present disclosure, a band gap of material of the second metal oxide semiconductor layer is equal to or less than 3.2 eV.

In an exemplary embodiment of the present disclosure, a conduction band of material of the second metal oxide semiconductor layer is greater than a conduction band of material of the first metal oxide semiconductor layer, and a Fermi energy level of the material of the second metal oxide semiconductor layer is greater than a Fermi energy level of the material of the first metal oxide semiconductor layer.

In an exemplary embodiment of the present disclosure, a band gap of material of the second metal oxide semiconductor layer is greater than a band gap of material of the first metal oxide semiconductor layer, the carrier concentration in the first metal oxide semiconductor layer is greater than a carrier concentration in the second metal oxide semiconductor layer; the hall mobility of the carriers in the first metal oxide semiconductor layer is greater than hall mobility of carriers in the second metal oxide semiconductor layer.

In an exemplary embodiment of the present disclosure, a thickness of the first metal oxide semiconductor layer is within a range of 100 to 300 angstroms; a thickness of the second metal oxide semiconductor layer is within a range of 200 to 400 angstroms.

In an exemplary embodiment of the present disclosure, material of the first metal oxide semiconductor layer is one of indium tin oxide, indium zinc oxide, indium gallium tin oxide, indium tin zinc oxide, indium gallium zinc tin oxide, first indium gallium zinc oxide, second indium gallium zinc oxide and third indium gallium zinc oxide;

wherein in the first indium gallium zinc oxide, in terms of an atomic molar number, indium:gallium:zinc=1:(0.7 to 1.3):(0.7 to 1.3); in the second indium gallium zinc oxide, in terms of an atomic molar number, indium:gallium:zinc=4:(1.7 to 2.3):(2.7 to 3.3); in the third indium gallium zinc oxide, in terms of an atomic molar number, indium:gallium:zinc=4:(2.7 to 3.3):(1.7 to 2.3).

In an exemplary embodiment of the present disclosure, material of the second metal oxide semiconductor layer is amorphous material, and material of the second metal oxide semiconductor layer is indium gallium zinc oxide or aluminum doped indium gallium zinc oxide.

In an exemplary embodiment of the present disclosure, the gate insulating layer includes a first silicon oxide layer, and the first metal oxide semiconductor layer is provided on a surface of the first silicon oxide layer away from the gate;

the metal oxide thin film transistor further includes a second silicon oxide layer provided on a side of the second metal oxide semiconductor layer away from the gate insulating layer;

an atomic percentage of oxygen in the second silicon oxide layer is greater than an atomic percentage of oxygen in the first silicon oxide layer.

According to a second aspect of the present disclosure, a method for preparing a metal oxide thin film transistor is provided and includes: forming a gate, a gate insulating layer, an active layer and a source-drain metal layer stacked on a side of a backplane, wherein the active layer and the gate are provided on both sides of the gate insulating layer, respectively, and the source-drain metal layer is provided on a side of the active layer away from the backplane; wherein forming the active layer on the side of the backplane includes:

forming a first metal oxide semiconductor material layer and a second metal oxide semiconductor material layer on the side of the backplane, providing the first metal oxide semiconductor material layer on a side of the gate insulating layer away from the gate, and providing the second metal oxide semiconductor material layer on a surface of the first metal oxide semiconductor material layer away from the gate; wherein a carrier concentration in the first metal oxide semiconductor material layer is greater than 1×10²⁰ cm⁻³, hall mobility of carriers in the first metal oxide semiconductor material layer is greater than 20 cm²/(V·s), and a total atomic percentage of indium and zinc in the first metal oxide semiconductor material layer is greater than 40%;

forming a first metal oxide semiconductor layer and a second metal oxide semiconductor layer by patterning the first metal oxide semiconductor material layer and the second metal oxide semiconductor material layer.

In an exemplary embodiment of the present disclosure, forming the gate insulating layer includes:

forming a first silicon oxide layer, wherein the first silicon oxide layer is provided on a surface of the first metal oxide semiconductor layer away from the second metal oxide semiconductor layer;

wherein when forming the first silicon oxide layer, a ratio of a nitrous oxide flow rate to a silane flow rate is (50 to 70): 1, and a temperature is within a range of 150 to 200° C.

In an exemplary embodiment of the present disclosure, the method for preparing the metal oxide thin film transistor further includes:

forming a second silicon oxide layer, wherein the second silicon oxide layer and the active layer are located on a same side of the backplane, and the second silicon oxide layer is located on a side of the second metal oxide semiconductor layer away from the first metal oxide semiconductor layer;

wherein when forming the second silicon oxide layer, a ratio of a nitrous oxide flow rate to a silane flow rate is (60 to 80): 1, and a temperature is within a range of 200 to 250° C.

According to a second aspect of the present disclosure, an array substrate is provided and includes any one of the above metal oxide thin film transistors.

The metal oxide thin film transistor, the method for preparing the metal oxide thin film transistor and the array substrate provided by the present disclosure, the active layer includes a first metal oxide semiconductor layer and a second metal oxide semiconductor layer that are stacked. The first metal oxide semiconductor layer is used to isolate the second metal oxide semiconductor layer from the gate insulating layer, such that an actual channel of the metal oxide thin film transistor is located in the second metal oxide semiconductor layer. Since the first metal oxide semiconductor layer and the second metal oxide semiconductor layer are both metal oxide semiconductor materials with similar material type, the number of defects at an interface between the second metal oxide semiconductor layer and the first metal oxide semiconductor layer is small, which reduces the number of carriers captured by the defects at the interface and increases the number of carriers in the actual channel, thereby improving carrier mobility of the metal oxide thin film transistor, and increasing an on-state current (I) and improving the stability of the metal oxide thin film transistor. Moreover, the first metal oxide semiconductor layer has a high carrier concentration, a high hall mobility and a high atomic percentage of indium and zinc. Thus, when the metal oxide thin film transistor works, the first metal oxide semiconductor layer enables to inject the carriers into the second metal oxide semiconductor layer, so as to further increase the carrier concentration in the actual channel and reduce density of the defects at the interface, further improve the on-state current of the metal oxide thin film transistor and improve the stability of the metal oxide thin film transistor. Photo-generated minority carriers generated from the actual channel recombine in the second metal oxide semiconductor layer, and the photo-generated minority carriers are not easily to be captured by the gate, nor by the defects at the interface between the first metal oxide semiconductor layer and the gate insulating layer. This is equivalent to reducing a concentration of photo-generated majority carriers, which in turn may improve light stability, positive bias thermal stability (PBTS) and negative bias thermal stability (NBTS) of the metal oxide thin film transistor.

### BRIEF DESCRIPTION OF THE DRAWINGS

The above and other features and advantages of the present disclosure will become more apparent from the detailed description of embodiments thereof with reference to the drawings.

FIG. 1 is a structural diagram of a BCE type oxide thin film transistor in the related art.

FIG. 2 is a schematic diagram of defect distribution and carriers accumulation in an active layer of a BCE type oxide thin film transistor in the related art.

FIG. 3 is a structural diagram of a metal oxide thin film transistor according to an embodiment of the present disclosure.

FIG. 4 is a structural diagram of a metal oxide thin film transistor according to an embodiment of the present disclosure.

FIG. 5 is a schematic diagram of defect distribution and carriers accumulation in an active layer of a metal oxide thin film transistor according to the embodiment of the present disclosure.

FIG. 6 is a structural diagram of a metal oxide thin film transistor according to an embodiment of the present disclosure.

FIG. 7 is a structural diagram of a metal oxide thin film transistor according to an embodiment of the present disclosure.

FIG. 8 is a structural diagram of forming a gate of a bottom-gate type metal oxide thin film transistor according to an embodiment of the present disclosure.

FIG. 9 is a structural diagram of forming a gate insulating layer of a bottom-gate type metal oxide thin film transistor according to an embodiment of the present disclosure.

FIG. 10 is a structural diagram of forming an active layer of a bottom-gate type metal oxide thin film transistor according to an embodiment of the present disclosure.

FIG. 11 is a structural diagram of forming a source-drain metal layer of a bottom-gate type metal oxide thin film transistor according to an embodiment of the present disclosure.

FIG. 12 is a structural diagram of an array substrate according to an embodiment of the present disclosure.

FIG. 13 is a schematic diagram showing performance of indium zinc oxide under different sputtering conditions according to an embodiment of the present disclosure.

FIG. 14 is a schematic diagram showing performance of indium zinc oxide under different annealing conditions according to an embodiment of the present disclosure.

### REFERENCE NUMERALS

100 backplane; 200 gate; 300 gate insulating layer; 310 first silicon oxide layer; 320 first silicon nitride layer; 400 active layer; 401 defect; 410 first metal oxide semiconductor layer; 420 second metal oxide semiconductor layer; 430 third metal oxide semiconductor layer; 500 source-drain metal layer; 510 source; 520 drain; 610 interlayer dielectric layer; 620 passivation layer; 621 second silicon oxide layer; 622 third silicon oxide layer; 623 second silicon nitride layer; 010 gate layer; 021 first semiconductor layer; 022 second semiconductor layer; 030 source-drain layer; 040 first passivation layer; 050 planarization layer; 060 common electrode layer; 070 second passivation layer; 080 pixel electrode layer; 090 alignment layer.

### DETAILED DESCRIPTION

Exemplary embodiments will now be described more fully with reference to the drawings. However, the exemplary embodiments can be implemented in a variety of forms and should not be construed as being limited to examples set forth herein; rather, these embodiments are provided such that the present disclosure will be more full and complete so as to convey the idea of the exemplary embodiments to those skilled in the related art. The described features, structures, or characteristics may be combined in any suitable manner in one or more embodiments. In the following description, many specific details are provided to give a thorough understanding of the embodiments of the present disclosure.

In the figures, thicknesses of regions and layers may be exaggerated for clarity. The same reference numerals in the drawings denote the same or similar structures, and thus their detailed descriptions will be omitted.

The described features, structures, or characteristics may be combined in any suitable manner in one or more embodiments. In the following description, numerous specific details are provided to give a thorough understanding of the embodiments of the present disclosure. However, those skilled in the art will appreciate that the technical solutions of the present disclosure may be practiced without one or more of the specific details, or other methods, components, materials, and the like may be employed. In other instances, well-known structures, materials or operations are not shown or described in detail to avoid obscuring main technical ideas of the present disclosure.

The terms “a”, “an”, “the” are used to indicate the presence of one or more elements/components/and the like; the terms “including” and “having” are used to indicate an open-ended inclusive meaning and refer to additional elements/components/and the like may be present in addition to the listed elements/components/and the like. The terms “first” and “second” and the like are used only as labels and are not intended to limit the number of objects.

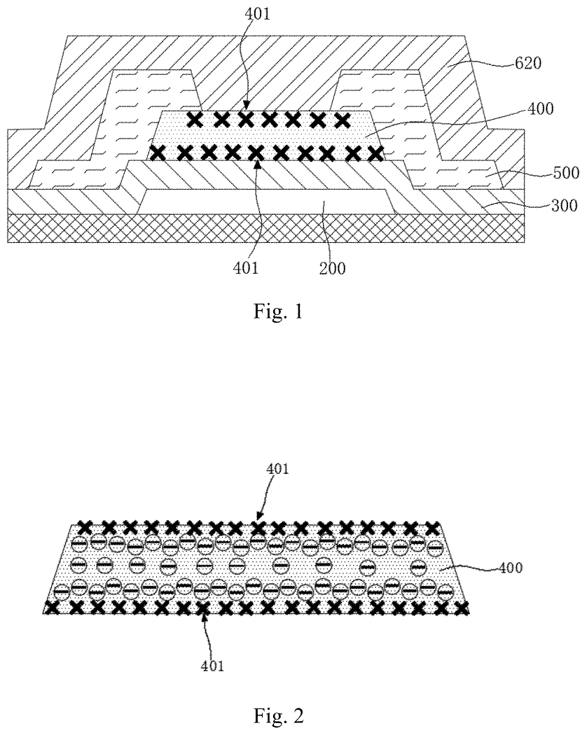

In the related art, as shown in FIG. 1, when a source-drain metal layer 500 of a BCE type oxide thin film transistor is etched, an active layer 400 may be eroded by etching solution of the source-drain metal layer, and an actual channel are in contact with a gate insulating layer 300 and a passivation layer 620, respectively. The etching solution of the source-drain metal layer has great damage to an oxide semiconductor, forming a large number of defects 401 in the active layer 400. When the active layer 400 is in contact with the gate insulating layer 300 or the passivation layer 620, defects 401 are generated at an interface. As shown in FIG. 2, these defects 401 trap carriers in the active layer 400, causing carriers to accumulate at the defects 401 and reducing carrier concentration and mobility in the active layer 400. This leads to a significant decrease in mobility and stability of the oxide thin film transistor, which seriously affects device characteristics.

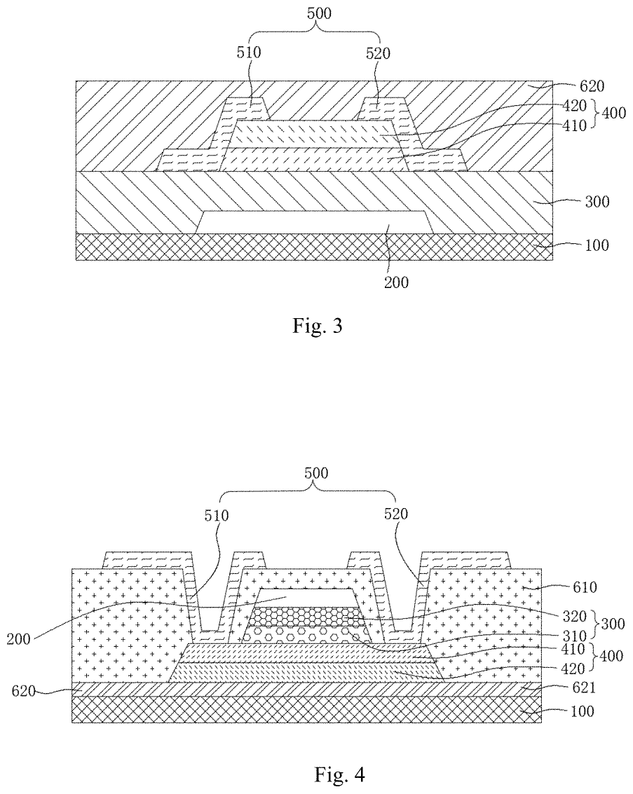

The present disclosure provides a metal oxide thin film transistor. As shown in FIG. 3 and FIG. 4, the metal oxide thin film transistor includes a gate 200, a gate insulating layer 300, an active layer 400 and a source-drain metal layer 500 stacked on a side of a backplane 100. The active layer 400 and the gate 200 are provided on both sides of the gate insulating layer 300, respectively, and the source-drain metal layer 500 is provided on a side of the active layer 400 away from the backplane 100, the active layer 400 includes:

a first metal oxide semiconductor layer 410 provided on a side of the gate insulating layer 300 away from the gate 200; wherein a carrier concentration in the first metal oxide semiconductor layer 410 is greater than 1×10²⁰ cm⁻³, hall mobility of carriers in the first metal oxide semiconductor layer 410 is greater than 20 cm²/(V·s), and a total atomic percentage of indium and zinc in the first metal oxide semiconductor layer 410 is greater than 40%;

a second metal oxide semiconductor layer 420 provided on a surface of the first metal oxide semiconductor layer 410 away from the gate 200.

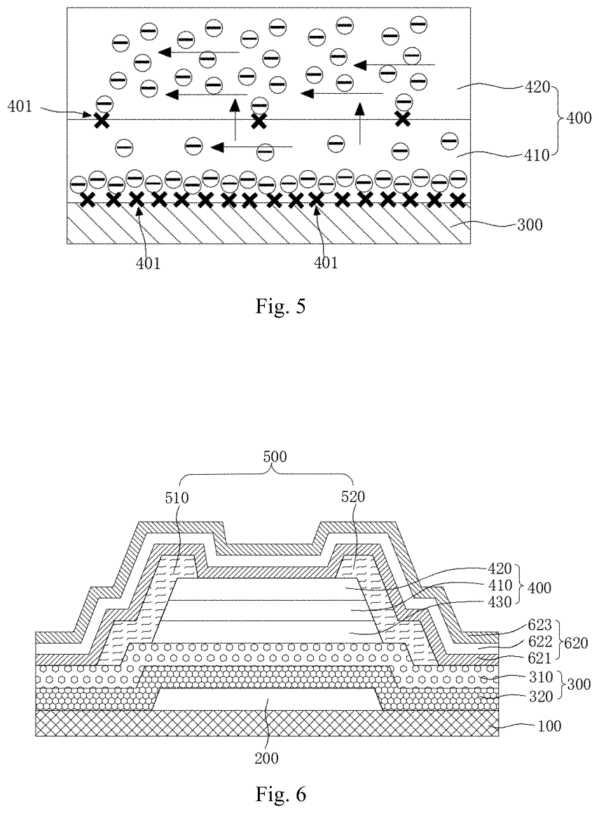

In the metal oxide thin film transistor provided by the present disclosure, as shown in FIG. 5, the active layer 400 includes a first metal oxide semiconductor layer 410 and a second metal oxide semiconductor layer 420 that are stacked. The first metal oxide semiconductor layer 410 is used to isolate the second metal oxide semiconductor layer 420 from the gate insulating layer 300, such that the actual channel of the metal oxide thin film transistor is located in the second metal oxide semiconductor layer 420. Since the first metal oxide semiconductor layer 410 and the second metal oxide semiconductor layer 420 are both metal oxide semiconductor materials with similar material type, the number of defects 401 at an interface between the second metal oxide semiconductor layer 420 and the first metal oxide semiconductor layer 410 is small, which reduces the number of carriers captured by the defects 401 at the interface and increases the number of carriers in the actual channel, thereby improving carrier mobility of the metal oxide thin film transistor, and increasing an on-state current (Iₒₙ) and improving the stability of the metal oxide thin film transistor. Moreover, the first metal oxide semiconductor layer 410 has the high carrier concentration, the high hall mobility and the high atomic percentage of indium and zinc. Thus, when the metal oxide thin film transistor works, the first metal oxide semiconductor layer 410 enables to inject the carriers into the second metal oxide semiconductor layer 420, so as to further increase the carrier concentration in the actual channel and reduce density of the defects 401 at the interface, further improve the on-state current of the metal oxide thin film transistor and improve the stability of the metal oxide thin film transistor. Photo-generated minority carriers generated from the actual channel recombine in the second metal oxide semiconductor layer 420, and the photo-generated minority carriers are not easily to be captured by the gate 200, nor by the defects 401 at the interface between the first metal oxide semiconductor layer 410 and the gate insulating layer 300. This is equivalent to reducing a concentration of photo-generated majority carriers, which in turn may improve light stability, positive bias thermal stability (PBTS) and negative bias thermal stability (NBTS) of the metal oxide thin film transistor.

In the related art, as shown in FIG. 1 and FIG. 2, the BCE type oxide thin film transistor adopts a metal oxide semiconductor structure with a single layer, and the metal oxide semiconductor with the single layer is directly connected to the gate insulating layer 300 as the actual channel. Since materials of the metal oxide semiconductor and the gate insulating layer 300 are different, a large number of defects 401 exist at an interface between the metal oxide semiconductor and the gate insulating layer 300, and the number of the defects 401 is one order of magnitude higher than that at the interface between the first metal oxide semiconductor layer 410 and the second metal oxide semiconductor layer 420, which results in a large number of carriers in the actual channel being captured by the defects 401, leading to low carrier mobility, low on-state current and low stability of the BCE-type oxide thin film transistor in the related art. Moreover, the photo-generated minority carriers generated by the metal oxide semiconductor in the related art are more likely to be captured by the gate 200, and also easily captured by the defects 401 at the interface between the metal oxide semiconductor and the gate insulating layer 300, which results in a relatively high concentration of photo-generated majority carriers. Thus, the BCE type oxide thin film transistor in the related art has low light stability, low positive bias thermal stability and low negative bias thermal stability.

Hereinafter, structure, principle and effect of the metal oxide thin film transistor provided by the present disclosure will be further explained and described with reference to the accompanying drawings.

The metal oxide thin film transistor provided by the present disclosure may be a top-gate type metal oxide thin film transistor or a bottom-gate type metal oxide thin film transistor.

For example, in an embodiment of the present disclosure, the metal oxide thin film transistor is a bottom-gate type metal oxide thin film transistor. As shown in FIG. 3, the metal oxide thin film transistor may include a gate 200, a gate insulating layer 300, a first metal oxide semiconductor layer 410, a second metal oxide semiconductor layer 420 and a source-drain metal layer 500 that are stacked on a backplane in sequence. The gate 200 is provided on a side of the backplane 100, the gate insulating layer 300 is provided on a side of the gate 200 away from the backplane 100, and the first metal oxide semiconductor layer 410 is provided on a side of the gate insulating layer 300 away from the backplane 100. A carrier concentration in the first metal oxide semiconductor layer 410 is greater than 1×10²⁰ cm⁻³, hall mobility of carriers in the first metal oxide semiconductor layer 410 is greater than 20 cm²/(V·s), and a total atomic percentage of indium and zinc in the first metal oxide semiconductor layer 410 is greater than 40%; the second metal oxide semiconductor layer 420 is provided on a surface of the first metal oxide semiconductor layer 410 away from the gate 200 for forming a source 510 and a drain 520 of the metal oxide thin film transistor.

For another example, in another embodiment of the present disclosure, as shown in FIG. 4, the metal oxide thin film transistor is a top-gate metal oxide thin film transistor, and may include a second metal oxide semiconductor layer 420, a first metal oxide semiconductor layer 410, a gate insulating layer 300, a gate 200 and a source-drain metal layer 500 that are stacked on a backplane 100 in sequence. The first metal oxide semiconductor is provided on a surface of the second metal oxide semiconductor layer 420 away from the backplane 100, the gate insulating layer 300 is provided on a side of the first metal oxide semiconductor layer 410 away from the backplane 100; the source-drain metal layer 500 is provided on the side of the first metal oxide semiconductor layer 410 away from the backplane 100, for forming a source 510 and a drain 520 of the metal oxide thin film transistor. A carrier concentration in the first metal oxide semiconductor layer 410 is greater than 1×10²⁰ cm⁻³, hall mobility of carriers in the first metal oxide semiconductor layer 410 is greater than 20 cm²/(V·s), and a total atomic percentage of indium and zinc in the first metal oxide semiconductor layer 410 is greater than 40%. Further, the metal oxide thin film transistor may further include a buffer layer located between the second metal oxide semiconductor layer 420 and the backplane 100, an interlayer dielectric layer 610 located on a side of the gate 200 away from the backplane 100, the source-drain metal layer 500 is provided on a side of the interlayer dielectric layer 610 away from the backplane 100 and is connected to the first metal oxide semiconductor layer 410 through a via hole.

In the metal oxide thin film transistor provided by the present disclosure, the backplane 100 may include a base substrate, and the base substrate may be a base substrate of an inorganic material, or a base substrate of an organic material. For example, in an embodiment of the present disclosure, a material of the base substrate may be glass material such as soda-lime glass, quartz glass, sapphire glass, or the like, or may be metal material such as stainless steel, aluminum, and nickel. In another embodiment of the present disclosure, material of the base substrate may be Polymethyl methacrylate (PMMA), Polyvinyl alcohol (PVA), Polyvinyl phenol (PVP), Polyether sulfone (PES), Polyimide, Polyamide, Polyacetal, Poly carbonate (PC), Polyethylene terephthalate (PET), Polyethylene naphthalate (PEN) or a combination thereof. In another embodiment of the present disclosure, the base substrate may also be a flexible base substrate, for example, a material of the base substrate may be polyimide (PI). The base substrate may also be a composite of multi-layer material. For example, in an embodiment of the present disclosure, the base substrate may include a bottom film layer (Bottom Film), a pressure-sensitive adhesive layer, a first polyimide layer and a second polyimide layer that are stacked in sequence.

In some embodiments of the present disclosure, the base substrate is made of an insulating material, and the base substrate may be used as the backplane 100 of the present disclosure. The gate 200, the active layer 400 and the like may be formed on a side of the base substrate.

In other embodiments of the present disclosure, the backplane 100 may further include an insulating material layer between the gate 200 and the base substrate, and the gate 200 is provided on a side of the insulating material layer away from the base substrate. Further, other functional film layers, such as a light shielding layer, an electromagnetic shielding layer, and the like, may also be provided between the base substrate and the insulating material layer. In some embodiments, these functional film layers may also be formed with functional Devices, such as these functional film layers, can also form as electroluminescent devices, photoelectric conversion devices, switching devices, and the like, located between the substrate and the insulating material layer. Optionally, when the metal oxide thin film transistor is a top-gate metal oxide thin film transistor, the insulating material layer may be reused as a buffer layer of the metal oxide thin film transistor.

In the metal oxide thin film transistor provided by the present disclosure, the gate 200 is used to control a conducting state of the metal oxide thin film transistor. A material of the gate 200 is a conductive material, such as, a metal material, a conductive metal oxide material, a conductive polymer material, a conductive composite material or a combination thereof. Exemplarily, the metal material may be platinum, gold, silver, aluminum, chromium, nickel, copper, molybdenum, titanium, magnesium, calcium, barium, sodium, palladium, iron, manganese, or combinations thereof. The conductive metal oxide material may be InO₂, SnO₂, indium tin oxide (ITO), fluorine doped tin oxide (FTO), aluminum doped zinc oxide (AZO), gallium doped zinc oxide (GZO), or combinations thereof. The conductive polymer material may be polyaniline, polypyrrole, polythiophene, polyacetylene, poly (3, 4-ethylenedioxythiophene)/polystyrene sulfonic acid (PEDOT/PSS) or a combination thereof, or a material of the above polymer doped with dopants such as acids (such as hydrochloric acid, sulfuric acid, sulfonic acid, and the like), Lewis acids (such as PF₆, AsF₅, FeCl₃, and the like), halogen atoms (such as iodine), and metal atoms (such as sodium or potassium). The conductive composite material may be a conductive composite material dispersed with carbon black, graphite powder, metal fine particles, and the like.

Optionally, a gate material layer may be formed by physical vapor deposition (PVD), chemical vapor deposition (CVD), spin coating, and the like. Then, a patterning operation is performed to form the gate 200. Of course, the gate 200 may also be directly formed by methods such as screen printing, which is not limited in the present disclosure.

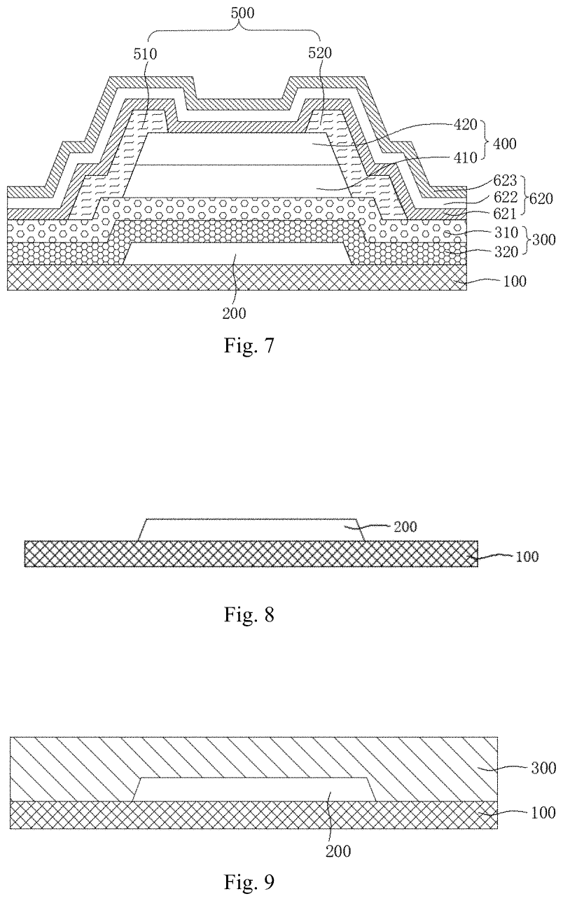

In the metal oxide thin film transistor provided by the present disclosure, the gate insulating layer 300 is used to isolate the gate 200 from the first metal oxide semiconductor layer 410. Optionally, as shown in FIG. 4, FIG. 6 and FIG. 7, the gate insulating layer 300 may include a first silicon oxide layer 310, and the first metal oxide semiconductor layer 410 is arranged on a side of the first silicon oxide layer 310 away from the gate 200. A material of the first silicon oxide layer 310 is silicon oxide, which may cooperate with a metal oxide in the first metal oxide semiconductor layer 410 to prevent the first metal oxide semiconductor layer 410 from being conductive. In one embodiment of the present disclosure, as shown in FIG. 4 and FIG. 7, the first metal oxide semiconductor layer 410 is provided on a surface of the first silicon oxide layer 310 away from the gate 200.

Optionally, the first silicon oxide layer 310 may have relatively high oxygen content, so as to reduce the defects 401 at the interface between the first silicon oxide layer 310 and the first metal oxide semiconductor layer 410 (particularly, to reduce the defect caused by lack of oxygen element in the first metal oxide semiconductor layer 410), so as to improve the stability of the first metal oxide semiconductor layer 410. In an embodiment of the present disclosure, a first silicon oxide material layer may be prepared under a condition of a ratio of nitrous oxide flow rate to a silane flow rate being (50 to 70): 1 and a temperature being within a range of 150 to 200° C. The silicon oxide material layer is then patterned to form the first silicon oxide layer 310. In another embodiment of the present disclosure, the first silicon oxide material layer may be prepared under a condition of a ratio of nitrous oxide flow rate to a silane flow rate being (50 to 70): 1 and a temperature being within a range of 150 to 200° C. The silicon material layer may be directly used as the first silicon oxide layer 310 without a patterning operation. In the present disclosure, a flow rate of a gas is a volume flow rate commonly used in the art and a unit may be sccm (Standard Cubic Centimeter per Minute).

Optionally, as shown in FIG. 4, FIG. 6 and FIG. 7, the gate insulating layer 300 may further include a first silicon nitride layer 320 provided between the gate 200 and the first silicon oxide layer 310. A material of the silicon nitride layer 320 is silicon nitride. The first silicon nitride layer 320 may be used to isolate the gate 200 from the first silicon oxide layer 310, and may be used to adjust a parasitic capacitance between the gate 200 and the active layer 400 of the metal oxide thin film transistor, so as to adjust a threshold voltage of the metal oxide thin film transistor. Moreover, the silicon nitride used in the first silicon nitride layer 320 has a higher compactness, which may more effectively protect the gate 200 and prevent the gate 200 from being eroded or prevent the material of the gate 200 from eroding other film layers. In an embodiment of the present disclosure, a first silicon nitride material layer may be formed first, and then a patterning operation is performed on the first silicon nitride material layer to form the first silicon nitride layer 320. In another embodiment of the present disclosure, a first silicon nitride material layer may be formed on a side of the gate 200 away from the backplane 100 first, and the first silicon nitride material layer may be directly used as the first silicon nitride layer 320 without the patterning operation.

It may be understood that, in some embodiments, the first silicon oxide material layer and the first silicon nitride material layer that are stacked may also be formed first, and then the first silicon oxide material layer and the first silicon nitride material layer may be patterned to form the first silicon nitride layer 320 and the first silicon oxide layer 310.

In the metal oxide thin film transistor provided by the present disclosure, the active layer 400 includes a first metal oxide semiconductor layer 410 and a second metal oxide semiconductor layer 420 that are stacked. A material of the first metal oxide semiconductor layer 410 may be a material with a relatively high carrier concentration and a relatively high hall mobility, so as to improve the capability of injecting carriers into the second metal oxide semiconductor layer 420, and further improve the carrier concentration in the second metal oxide semiconductor layer 420, thereby further increasing the carrier mobility and the on-state current of the metal oxide thin film transistor.

Optionally, the carrier concentration in the first metal oxide semiconductor layer 410 is equal to or less than 1×10²¹ cm⁻³, so as to avoid the carrier concentration of the first metal oxide semiconductor layer 410 being too high to present too strong conductivity, and especially to maintain appropriate semiconductor characteristics under the condition that the first metal oxide semiconductor layer 410 has a suitable preparable thickness. In other words, in the present disclosure, the conductive characteristics and semiconductor characteristics of the first metal oxide semiconductor layer 410 need to be balanced, not only to enable the first metal oxide semiconductor layer 410 to have a relatively high carrier concentration to improve the on-state current of the metal oxide thin film transistor, but also to prevent the metal oxide thin film transistor from having too much leakage current in an off state due to the strong conductivity of the first metal oxide semiconductor layer 410.

Optionally, the hall mobility of the carriers in the first metal oxide semiconductor layer 410 is within a range of 25 cm²/(V·s) to 50 cm²/(V·s), so as to avoid the carrier concentration of the first metal oxide semiconductor layer 410 being too large to present too strong conductivity, and especially to maintain appropriate semiconductor characteristics under the condition that the first metal oxide semiconductor layer 410 has a suitable preparable thickness.

Optionally, a thickness of the first metal oxide semiconductor layer 410 may be within a range of 100 to 300 angstroms. In this way, the defects 401, easily caused by uneven preparation due to too thin thickness of the first metal oxide semiconductor layer 410, may be prevented, which may improve uniformity of the first metal oxide semiconductor layer 410 and further improve the stability of the metal oxide thin film transistor. Moreover, a metal oxide material with low carrier concentration and low carriers hall mobility may be prevented from being selected due to too thick of the first metal oxide semiconductor layer 410, and the thickness of the first metal oxide semiconductor layer 410 may also be reduced, which is conducive to the lightness and thinning of the metal oxide thin film transistor. Preferably, the thickness of the first metal oxide semiconductor layer 410 may be 150 to 250 angstroms, so as to further balance the uniformity, material performance, lightness and thinning of the first metal oxide semiconductor layer 410.

Optionally, the material of the first metal oxide semiconductor layer 410 may be a metal oxide semiconductor material rich in indium and zinc, a total atomic percentage of indium and zinc is greater than 40%. For example, the material of the first metal oxide semiconductor layer 410 may be one of indium tin oxide (ITO), indium zinc oxide (IZO), indium gallium tin oxide (IGTO), indium tin zinc oxide (ITZO), first indium gallium zinc tin oxide (IGZYO), second indium gallium zinc tin oxide (IGZXO), first indium gallium zinc oxide IGZO (111), second indium gallium zinc oxide IGZO-1 (423), and third indium gallium zinc oxide IGZO (432), X and Y both represent tin, and X and Y represent different amounts of tin respectively. In the first indium gallium zinc oxide IGZO (111), in terms of an atomic molar number, indium:gallium:zinc=1: (0.7 to 1.3): (0.7 to 1.3); in the second indium gallium zinc oxide IGZO-1 (423), in terms of an atomic molar number, indium:gallium:zinc=4: (1.7 to 2.3): (2.7 to 3.3); in the third indium gallium zinc oxide IGZO (432), in terms of an atomic molar number, indium:gallium:zinc=4: (2.7 to 3.3): (1.7 to 2.3).

In an embodiment of the present disclosure, the material of the first metal oxide semiconductor layer 410 may be IZO or ITO. In this way, majority carriers in the first metal oxide semiconductor layer 410 may be electrons, and have characteristics of injecting electrons into the second metal oxide semiconductor layer 420, so as to improve concentration of electrons that serves as the majority carriers in the second metal oxide semiconductor layer 420, thereby further improving the carrier mobility and the on-state current of the metal oxide thin film transistor.

Material types of IZO or ITO and the gate insulating layer 300 differ greatly, and there are high-density defects 401 at the interface between the first metal oxide semiconductor layer 410 and the gate insulating layer 300. Thus, the first metal oxide semiconductor layer 410 may not only protect the second metal oxide semiconductor layer 420 and reduce the density of defect state of the second metal oxide semiconductor layer 420, but also serve as a carrier generation layer to inject electrons into the second metal oxide semiconductor layer 420.

Optionally, the first metal oxide semiconductor material layer may be formed first, and then the first metal oxide semiconductor material layer may be patterned to form the first metal oxide semiconductor layer 410. Further optionally, the first metal oxide semiconductor material layer may be formed by deposition. For example, the first metal oxide semiconductor material layer may be formed by magnetron sputtering. Further optionally, semiconductor performance of the first metal oxide semiconductor material layer may be adjusted by adjusting process conditions of the magnetron sputtering. For example, FIG. 13 shows material performance of a first metal oxide semiconductor material layer formed under different process conditions when the first metal oxide semiconductor material layer is formed by magnetron sputtering indium zinc oxide (IZO). According to FIG. 13, under the condition that a partial pressure proportion of oxygen in gas atmosphere during the magnetron sputtering does not exceed 3%, the higher the partial pressure proportion of oxygen in the gas atmosphere, the lower the carrier concentration in the first metal oxide semiconductor layer 410, and the higher the hall mobility of the carriers. When the first metal oxide semiconductor material layer is formed by the magnetron sputtering indium zinc oxide, the gas atmosphere may be selected and determined according to specific requirement, so as to fine-tune the performance of the first metal oxide semiconductor layer 410. Optionally, when the first metal oxide semiconductor material layer is formed by the magnetron sputtering indium zinc oxide, the partial pressure proportion of oxygen in the gas atmosphere is not more than 3%, and a deposition temperature is within a range of 25 to 300° C.

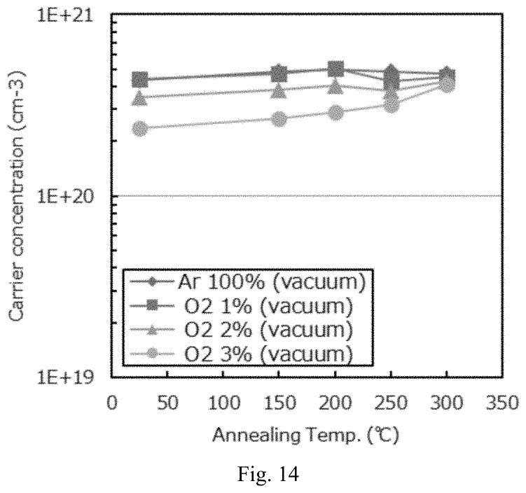

Further, after the first metal oxide semiconductor material layer is formed by the magnetron sputtering, the first metal oxide semiconductor material layer may also be annealed to further adjust the carrier concentration and the hall mobility of the carriers in the first metal oxide semiconductor layer 410. Exemplarily, FIG. 14 illustrates material performance of the first metal oxide semiconductor material layer composed of indium zinc oxide after annealing under different conditions. Referring to FIG. 14, it can be seen that under the condition that a partial pressure proportion of oxygen in the gas atmosphere does not exceed 3%, the higher the partial pressure proportion of oxygen in the gas atmosphere, the lower the carrier concentration in the first metal oxide semiconductor material layer; and the higher a annealing temperature is, the higher the carrier concentration is. In an embodiment of the present disclosure, when the first metal oxide semiconductor material layer composed of indium zinc oxide is annealed, the annealing temperature is within a range of 350 to 450° C., and the partial pressure proportion of oxygen in the gas atmosphere does not exceed 3%.

As shown in FIG. 4, FIG. 6 and FIG. 7, the second metal oxide semiconductor layer 420 is provided on a surface of the first metal oxide semiconductor layer 410 away from the gate 200, and is used as the actual channel of the metal oxide thin film transistor. Optionally, a band gap of the material of the second metal oxide semiconductor layer 420 is greater than that of the material of the first metal oxide semiconductor layer 410, and the carrier concentration in the first metal oxide semiconductor layer 410 is greater than that in the second metal oxide semiconductor layer 420, and the hall mobility of the carriers in the first metal oxide semiconductor layer 410 is greater than that in the second metal oxide semiconductor layer 420. Optionally, a conduction band of the material of the second metal oxide semiconductor layer 420 is greater than that of the material of the first metal oxide semiconductor layer 410, and a Fermi energy level of the material of the second metal oxide semiconductor layer 420 is greater than that of the material of the first metal oxide semiconductor layer 410. In this way, the second metal oxide semiconductor layer 420 may be prevented from being conductive under the carriers injection of the first metal oxide semiconductor layer 410, which in turn may improve the light stability, positive bias thermal stability (PBTS) and negative bias thermal stability (NBTS) of the metal oxide thin film transistor.

Optionally, the material of the second metal oxide semiconductor layer 420 may have a high band gap, which may improve accuracy of performance parameters of the metal oxide thin film transistor and expand preparation process window of the metal oxide thin film transistor. The preparation process window refers to a control range of the process parameters under the condition that the target requirements are met. The wider the preparation process window, the better the manufacturability of a material system, and the easier it is to achieve an established goal in the actual process. Exemplarily, the higher the band gap of the material of the second metal oxide semiconductor layer 420, the lower the sensitivity to a size of the second metal oxide semiconductor layer 420 and the wider an allowable size fluctuation range of the second metal oxide semiconductor layer 420 on the premise of achieving the required conductive characteristics, the easier it is to prepare the second metal oxide semiconductor layer 420 to achieve the required conductive characteristics in the actual preparation process, and the wider the preparation process window of the second metal oxide semiconductor layer 420.

Further optionally, the band gap of the material of the second metal oxide semiconductor layer 420 is equal to or greater than 3.0 eV, so as to improve the stability of the second metal oxide semiconductor layer 420, especially the light stability, the positive bias thermal stability (PBTS) and the negative bias thermal stability (NBTS) of the metal oxide thin film transistor.

Optionally, the band gap of the material of the second metal oxide semiconductor layer 420 is equal to or less than 3.2 eV to prevent the second metal oxide semiconductor layer 420 from having an excessively high threshold voltage.

Optionally, a thickness of the second metal oxide semiconductor layer 420 is 200 to 400 angstroms. In this way, it may be prevented that the second metal oxide semiconductor layer 420 are easily conductive due to its too large thickness, and it may also be prevented that a proportion of carriers lost by the defects 401 is too large due to its too small thickness.

Optionally, the material of the second metal oxide semiconductor layer 420 is amorphous metal oxide semiconductor, such as amorphous IGZO with CAAC (c-axis aligned crystalline) structure, aluminum doped IGZO, and the like. Exemplarily, the material of the second metal oxide semiconductor layer 420 may be one of first indium gallium zinc oxide IGZO (111), second indium gallium zinc oxide IGZO-1 (423), third indium gallium zinc oxide IGZO (432), fourth indium gallium zinc oxide IGZO-2 (136), fifth indium gallium zinc oxide IGZO (132), and sixth indium gallium zinc oxide IGZO (134). In the fourth indium gallium zinc oxide IGZO-2 (136), in terms of an atomic molar number, indium:gallium:zinc=1: (2.7 to 3.3): (5.7 to 6.3). In the fifth indium gallium zinc oxide IGZO (132), in terms of an atomic molar number, indium:gallium:zinc=1: (2.7 to 3.3): (1.7 to 2.3). In the sixth indium gallium zinc oxide IGZO (134), in terms of an atomic molar number, indium:gallium:zinc=1:(2.7 to 3.3):(3.7 to 4.3).

Optionally, the second metal oxide semiconductor material layer may be formed first, and then the second metal oxide semiconductor material layer may be patterned to form the second metal oxide semiconductor layer 420. Further optionally, the second metal oxide semiconductor material layer may be formed by deposition. For example, the second metal oxide semiconductor material layer may be formed by magnetron sputtering. When the second metal oxide semiconductor material layer is formed by the magnetron sputtering, a partial pressure proportion of oxygen in the gas atmosphere may be relatively high, so as to reduce density of the defects 401 of the second metal oxide semiconductor material layer. Preferably, the partial pressure proportion of oxygen in the gas atmosphere when the second metal oxide semiconductor material layer is formed is greater than that when the first metal oxide semiconductor material layer is formed.

In an embodiment of the present disclosure, when the second metal oxide semiconductor material layer is formed by sputtering, the partial pressure proportion of oxygen in the gas atmosphere does not exceed 3%.

In an embodiment of the present disclosure, a first metal oxide semiconductor material layer and a second metal oxide semiconductor material layer that are stacked may be formed first, and then the first metal oxide semiconductor material layer and the second metal oxide semiconductor material layer may be patterned in one patterning operation, so as to prepare the first metal oxide semiconductor layer 410 and the second metal oxide semiconductor layer 420. In this way, the density of the defects 401 generated in the patterning process of the first metal oxide semiconductor material layer may be reduced, and the density of the defects 401 at the interface between the first metal oxide semiconductor layer 410 and the second metal oxide semiconductor layer 420 may be further reduced. In addition, the number of patterning operations and the number of masks during the preparation of metal oxide thin film transistors may be reduced.

Optionally, as shown in FIG. 6, the active layer 400 may further include a third metal oxide semiconductor layer 430 located between the gate insulating layer 300 and the first metal oxide semiconductor layer 410 for protecting the first metal oxide semiconductor layer 410, which further improves the carrier mobility and the on-state current of the metal oxide thin film transistor. Moreover, it may further improve the light stability, the positive bias thermal stability (PBTS) and the negative bias thermal stability (NBTS) of the metal oxide thin film transistor. In some embodiments, the third metal oxide semiconductor layer 430 may adopt a metal oxide material with low carrier mobility to better shield the defects 401 at the interface between the third metal oxide semiconductor layer 430 and the gate insulating layer 300.

In the metal oxide thin film transistor provided by the present disclosure, as shown in FIG. 4, FIG. 6 and FIG. 7, the source-drain metal layer 500 is used to form a source 510 and a drain 520 of the metal oxide thin film transistor. Optionally, as shown in FIG. 6 and FIG. 7, for a bottom-gate type metal oxide thin film transistor, the source-drain metal layer 500 may cover a partial surface of the second metal oxide semiconductor layer 420 to ensure the connection between the source-drain metal layer 500 and the active layer 400. Further optionally, the source-drain metal layer 500 may also cover a partial side of the first metal oxide semiconductor layer 410. Optionally, as shown in FIG. 4, for a top-gate type metal oxide thin film transistor, the source-drain metal layer 500 may be provided on a side of an interlayer dielectric layer 610 away from the backplane 100, and connected with the first metal oxide semiconductor layer 410 through a via hole.

Optionally, the source-drain metal material layer may be formed first, and then the source-drain metal material layer may be patterned to form the source-drain metal layer 500. In some embodiments, dry etching is avoided in the process of patterning the source-drain metal material layer, and wet etching may be adopted to reduce damage of etching to the second metal oxide semiconductor layer 420 and improve the uniformity and accuracy of etching. Exemplarily, the source-drain metal layer 500 may include a molybdenum layer, a copper layer, and a molybdenum layer stacked in sequence on a side of the second metal oxide semiconductor layer 420 away from the backplane 100, a thickness of the molybdenum layer is 20 to 50 nanometers, and a thickness of the copper layer is 200 to 500 nanometers. The source-drain metal layer 500 with a Mo/Cu/Mo structure may be obtained by patterning the source-drain metal material layer with the Mo/Cu/Mo structure using the wet etching process.

Optionally, as shown in FIG. 3 and FIG. 4, the metal oxide thin film transistor provided by the present disclosure may further include a passivation layer 620. For the top-gate type metal oxide thin film transistor, the passivation layer 620 may be reused as a buffer layer to protect the second metal oxide semiconductor layer 420. For the bottom-gate type metal oxide thin film transistors, the passivation layer 620 may be used to protect the source-drain metal layer 500, the first metal oxide semiconductor layer 410, and the second metal oxide semiconductor layer 420. It may be understood that for the bottom-gate type metal oxide thin film transistor, the passivation layer 620 may expose at least a part of the source-drain metal layer 500, such that the metal oxide thin film transistor is electrically connected with other external conductive structures through the source-drain metal layer 500. Exemplarily, when the metal oxide thin film transistor is located on a display panel as a driving transistor, the passivation layer 620 exposes at least a part of the drain 520 of the metal oxide thin film transistor, such that the drain 520 of the metal oxide thin film transistor is electrically connected with a pixel electrode of the display panel.

As shown in FIGS. 4 and 6, the passivation layer 620 may include a second silicon oxide layer 621 provided on a surface of the second metal oxide semiconductor layer 420 away from the gate 200. A silicon oxide material with high oxygen content may be adopted in the second silicon oxide layer 621, so as to achieve the effect of oxygen supplement on the second metal oxide semiconductor layer 420, reduce or partially repair the defects 401 on the surface of the second metal oxide semiconductor layer 420, such that the loss, generated by the defects 401, of the carriers in the second metal oxide semiconductor layer 420 may be further reduced, and the carrier mobility and the stability of the metal oxide thin film transistor are further improved. Further, as shown in FIG. 4, for the top-gate type metal oxide thin film transistor, the silicon oxide layer 621 has a high compactness, which may further achieve a better protection effect on the source-drain metal layer 500.

Optionally, an atomic percentage of oxygen in the second silicon oxide layer 621 is greater than that in the first silicon oxide layer 310, so as to ensure that the second silicon oxide layer 621 may more effectively repair the defects 401 of the second metal oxide semiconductor layer 420.

Optionally, when the second silicon oxide layer 621 is formed, a ratio of a nitrous oxide flow rate to a silane flow rate is (60 to 80): 1, and a temperature is within a range of 200 to 250° C. In an embodiment of the present disclosure, the second silicon oxide material layer may be formed under the process conditions of the ratio of the nitrous oxide flow rate to the silane flow rate being (60 to 80): 1 and the temperature being within the range of 200 to 250° C., and then the second silicon oxide layer 621 may be patterned to form the second silicon oxide layer 621.

In an embodiment of the present disclosure, after forming the second silicon oxide material layer and the active layer 400 that are stacked, or after forming the second silicon oxide layer 621 and the active layer 400 that are stacked, an annealing operation may also be performed to further improve the effect of oxygen supplement of the second silicon oxide layer 621 on the second metal oxide semiconductor layer 420, and reduce the defects of the second metal oxide semiconductor layer 420 due to the lack of oxygen element.

Optionally, as shown in FIG. 6, the passivation layer 620 may further include a third silicon oxide layer 622 provided on a side of the silicon oxide layer 621 away from the gate 200. In an embodiment of the present disclosure, when preparing the third silicon oxide layer 622, the process conditions adopted may be as follows: a ratio of a nitrous oxide flow to a silane flow is (40 to 50): 1, and a temperature is within a range of 150 to 200° C.

Optionally, the passivation layer 620 may further include a second silicon nitride layer 623 provided on a side of the third silicon oxide layer 622 away from the gate 200.

In an embodiment of the present disclosure, the second silicon oxide material layer, the third silicon oxide material layer and the second silicon nitride material layer that are stacked may be formed first, and then the second silicon oxide material layer, the third silicon oxide material layer and the second silicon nitride material layer may be patterned to form the second silicon oxide layer 621, the third silicon oxide layer 622 and the second silicon nitride layer 623. Further, after forming the second silicon oxide material layer, the third silicon oxide material layer and the second silicon nitride material layer, or after forming the second silicon oxide layer 621, the third silicon oxide layer 622 and the second silicon nitride layer 623, the annealing operation may be performed again to further reduce the number of the defects 401 in the active layer 400 and improve the carrier mobility and the stability of the active layer 400, thereby further improving the on-state current and the light stability of the metal oxide thin film transistor.

Structure of a bottom-gate type metal oxide thin film transistor and a method for preparing the bottom-gate type metal oxide thin film transistor are further described and explained below, which is illustrated only as an example.

As shown in FIG. 7, the exemplary bottom-gate type metal oxide thin film transistor includes a gate 200, a gate insulating layer 300, an active layer 400, a source-drain metal layer 500, and a passivation layer 620 that are stacked on the backplane 100 in sequence.

The gate insulating layer 300 includes a first silicon nitride layer 320 and a first silicon oxide layer 310 that are stacked in sequence on a side of the gate 200 away from the backplane 100. The active layer 400 includes a first metal oxide semiconductor layer 410 and a second metal oxide semiconductor layer 420 that are stacked in sequence on a surface of the first silicon oxide layer 310 away from the backplane 100. The source-drain metal layer 500 is connected with a partial side of the first metal oxide semiconductor layer 410, a partial side of the second metal oxide semiconductor layer 420, and a partial surface of the second metal oxide semiconductor layer 420 away from the backplane 100, the passivation layer 620 covers a part of the source-drain metal layer 500 and a part of the active layer 400 exposed by the source-drain metal layer 500, and includes a second silicon oxide layer 621, a third silicon oxide layer 622 and a second silicon nitride layer 623, which are stacked in sequence on the side of the source-drain metal layer 500 away from the backplane 100.

Exemplarily, the exemplary bottom-gate type metal oxide thin film transistor may be prepared by the following method:

Step S110, as shown in FIG. 8, forming a gate material layer on a side of a backplane 100, and patterning the gate material layer to form a gate 200.

Step S120, as shown in FIG. 9, forming a first silicon nitride material layer and a first silicon oxide material layer that are stacked by depositing silicon nitride and silicon oxide in sequence on a side of the gate 200 away from the backplane 100. The first silicon nitride material layer and the first silicon oxide material layer serve as the first silicon nitride layer 320 and the first silicon oxide layer 310 of the bottom-gate type metal oxide thin film transistor, respectively without patterning operation. The first silicon nitride layer 320 and the first silicon oxide layer 310 form the gate insulation layer 300 of the bottom-gate type metal oxide thin film transistor.

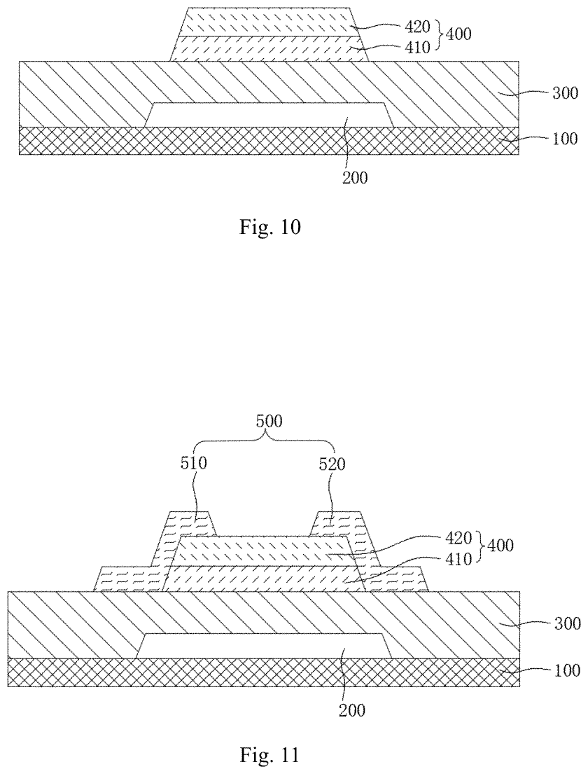

Step S130, as shown in FIG. 10, forming a first metal oxide semiconductor material layer and a second metal oxide semiconductor material layer in sequence on a side of the gate insulating layer 300 away from the backplane 100, then, forming the first metal oxide semiconductor layer 410 and the second metal oxide semiconductor layer 420 by patterning the first metal oxide semiconductor material layer and the second metal oxide semiconductor material layer. The first metal oxide semiconductor layer 410 and the second metal oxide semiconductor layer 420 form an active layer 400 of the bottom-gate type metal oxide thin film transistor.

Step S140, as shown in FIG. 11, forming a source-drain metal material layer on a side of the active layer 400 away from the backplane 100, then forming a source-drain metal layer 500 by patterning the source-drain metal material layer. The source-drain metal layer 500 forms a source 510 and a drain 520 of the bottom-gate type metal oxide thin film transistor.

Step S150, forming a second silicon oxide material layer by depositing silicon oxide on a side of the source-drain metal layer 500 away from the backplane 100, then performing oxygen supplement on the active layer 400 by annealing.

Step S160, forming a third silicon oxide material layer by depositing silicon oxide on a side of the second silicon oxide material layer away from the backplane 100; forming a second silicon nitride material layer by depositing silicon nitride on a side of the third silicon oxide material layer away from the backplane 100.

Step S170, forming a second silicon oxide layer 621, a third silicon oxide layer 622 and a second silicon nitride layer 623 by patterning the second silicon oxide material layer, the third silicon oxide material layer and the second silicon nitride material layer. The second silicon oxide layer 621, the third silicon oxide layer 622, and the second silicon nitride layer 623 form a passivation layer 620 of the bottom-gate type metal oxide thin film transistor.

It may be understood that the above structure of the bottom-gate type metal oxide thin film transistor and the method for preparing the bottom-gate type metal oxide thin film transistor are only an example. According to the metal oxide thin film transistor provided by the present disclosure, structure of the bottom-gate type metal oxide thin film transistor may also be other structure, and may also be prepared by other feasible method, which will not be described in detail herein.

Structure of a top-gate type metal oxide thin film transistor and a method for preparing the top-gate type metal oxide thin film transistor are further described and explained below, which is illustrated only as an example.

As shown in FIG. 4, the exemplary top gate type metal oxide thin film transistor includes a passivation layer 620, an active layer 400, a gate insulating layer 300, a gate 200, an interlayer dielectric layer 610, and a source-drain metal layer 500 that are stacked in sequence on a backplane 100.

The passivation layer 620 may be reused as a buffer layer of the top-gate type metal oxide thin film transistor, and may also be reused as an insulating material layer of the backplane 100 to protect the second metal oxide semiconductor layer 420. The passivation layer 620 may include a second silicon oxide layer 621 stacked on the backplane 100. The active layer 400 includes a second metal oxide semiconductor layer 420 and a first metal oxide semiconductor layer 410 that are stacked in sequence on a surface of the second silicon oxide layer 621 away from the backplane 100. The gate insulating layer 300 includes a first silicon oxide layer 310 and a first silicon nitride layer 320 that are stacked in sequence on a surface of the second metal oxide semiconductor layer 420 away from the backplane 100. The source-drain metal layer 500 is provided on a side of the interlayer dielectric layer 610 away from the backplane 100 and is connected with the first metal oxide semiconductor layer 410 through a via hole to form a source 510 and a drain 520. Optionally, a silicon oxide layer, a silicon nitride layer, a silicon oxynitride layer, or other inorganic insulating material layer for protecting the source-drain metal layer 500 may also be provided on a side of the source-drain metal layer 500 away from the backplane 100.

Exemplarily, the exemplary top-gate type metal oxide thin film transistor may be prepared by the following method:

Step S210, forming a second silicon oxide material layer by depositing silicon oxide on a side of a backplane 100, the second silicon oxide material layer may be used as a second silicon oxide layer 621 without patterning. The silicon oxide layer 621 may be used as a passivation layer 620 of the top-gate type metal oxide thin film transistor.

Step S220, forming a second metal oxide semiconductor material layer and a first metal oxide semiconductor material layer in sequence on a surface of the second silicon oxide layer 621 away from the backplane 100, forming a second metal oxide semiconductor layer 420 and a first metal oxide semiconductor layer 410 by patterning the second metal oxide semiconductor material layer and the first metal oxide semiconductor material layer. The second metal oxide semiconductor layer 420 and the first metal oxide semiconductor layer 410 form an active layer 400 of the top-gate type metal oxide thin film transistor.

Step S230, forming a first silicon oxide material layer and a first silicon nitride material layer in sequence on a surface of the first metal oxide semiconductor layer 410 away from the backplane 100, then forming the first silicon oxide layer 310 and the first silicon nitride layer 320 by patterning the first silicon oxide material layer and the first silicon nitride material layer. The first silicon oxide layer 310 and the first silicon nitride layer 320 form a gate insulating layer 300 of the top-gate type metal oxide thin film transistor.

Step S240, forming a gate material layer on a side of the first silicon nitride layer 320 away from the backplane 100, forming a gate 200 by patterning the gate material layer.

Step S250, forming an interlayer dielectric material layer by depositing an inorganic insulating material on a side of the gate 200 away from the backplane 100; forming an interlayer dielectric layer 610 by patterning the interlayer dielectric material layer.

Step S260, forming a source-drain metal material layer on a side of the interlayer dielectric layer 610 away from the backplane 100; forming the source-drain metal layer 500 by patterning the source-drain metal material layer.

It may be understood that the above structure of the top-gate type metal oxide thin film transistor and the method for preparing the top-gate type metal oxide thin film transistor are only an example. According to the metal oxide thin film transistor provided by the present disclosure, structure of the top-gate type metal oxide thin film transistor may also be other structure, and may also be prepared by other feasible method, which will not be described in detail herein.

The metal oxide thin film transistor provided by the present disclosure may be applied to camera devices, display devices, light-emitting devices, photoelectric devices, power generation devices, and the like. For example, it may be applied to digital cameras, OLED display panels, liquid crystal display panels, lighting lamps, fingerprint identification panels, thin-film solar cells, organic thin-film solar cells, and the like. Among these devices, the metal oxide thin film transistor provided by the present disclosure may be used as one or more of switching transistors, amplifiers, driving transistors, etc., which is not limited by the present disclosure.

Embodiments of the present disclosure also provides an array substrate, which includes any one of the metal oxide thin film transistors described in the above embodiments of the metal oxide thin film transistor. The array substrate may be OLED array substrate, LED array substrate, QD-OLED (quantum dot-organic light emitting diode) array substrate, array substrate for liquid crystal display panel or other types of array substrate for display device. Since the array substrate has any one of the metal oxide thin film transistors described in the above embodiments of the metal oxide thin film transistor, it has the same beneficial effect, which will not be repeated herein.

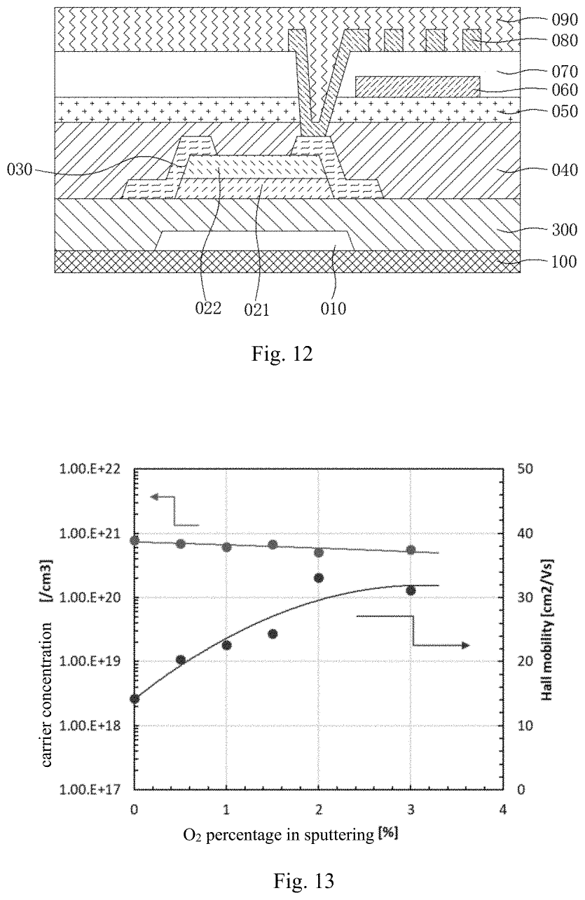

Next, an array substrate for a liquid crystal display panel is provided as an example to exemplarily explain and illustrate a specific application of the metal oxide thin film transistor provided by the present disclosure. As shown in FIG. 12, the array substrate of the example includes a backplane 100, a gate layer 010, a gate insulating layer 300, a first semiconductor layer 021, a second semiconductor layer 022, a source-drain layer 030, a first passivation layer 040, a planarization layer 050, a common electrode layer 060, a second passivation layer 070, a pixel electrode layer 080, and an alignment layer 090, which are stacked in sequence.

A plurality of bottom-gate type metal oxide thin film transistors are formed by the gate layer 010, the gate insulating layer 300, the first semiconductor layer 021, the second semiconductor layer 022, the source-drain layer 030, and the first passivation layer 040. The gate layer 010 includes the gate 200 of each metal oxide thin film transistor, and may further include a gate lead connected to the gate 200. The gate insulating layer 300 covers each gate 200 to isolate the gate 200 of each metal oxide thin film transistor from the first metal oxide semiconductor layer 410. The first semiconductor layer 021 includes a first metal oxide semiconductor layer 410 of each metal oxide thin film transistor. The second semiconductor layer 022 includes a second metal oxide semiconductor layer 420 of each metal oxide thin film transistor. The source-drain layer 030 includes a source-drain metal layer 500 of each metal oxide thin film transistor, which is used to form a source 510 and a drain 520 of each metal oxide thin film transistor, the source-drain layer 030 may further include a data lead connected to the source 510. The first passivation layer 040 includes a passivation layer 620 of the bottom-gate type metal oxide thin film transistor, and exposes at least a partial region of the drain 520 of each metal oxide thin film transistor.

The planarization layer 050 covers each bottom-gate type metal oxide thin film transistor to provide a planarization surface for the common electrode layer 060. The planarization layer 050 exposes at least a partial region of the drain 520 of each metal oxide thin film transistor. The common electrode layer 060 is provided on a side of the planarization layer 050 away from the backplane 100, which may include a plurality of plate electrodes. The second passivation layer 070 covers the common electrode layer 060 and exposes at least a partial region of the drain 520 of the metal oxide thin film transistor. The pixel electrode layer 080 may include a plurality of pixel electrodes passing through the first passivation layer 040, the second passivation layer 070 and the planarization layer 050 to be electrically connected with the drain 520 of the metal oxide thin film transistor. Each pixel electrode may be a slit electrode.

The present disclosure also provides a method for preparing a metal oxide thin film transistor, including: forming a gate 200, a gate insulating layer 300, an active layer 400 and a source-drain metal layer 500 stacked on a side of a backplane 100, the active layer 400 and the gate 200 are provided on both sides of the gate insulating layer 300, respectively, and the source-drain metal layer 500 is provided on a side of the active layer 400 away from the backplane 100; the forming the active layer 400 on the side of the backplane 100 includes:

forming a first metal oxide semiconductor material layer and a second metal oxide semiconductor material layer on the side of the backplane 100, providing the first metal oxide semiconductor material layer on a side of the gate insulating layer 300 away from the gate 200, and providing the second metal oxide semiconductor material layer on a surface of the first metal oxide semiconductor material layer away from the gate 200; wherein a carrier concentration in the first metal oxide semiconductor material layer is greater than 1×10²⁰ cm⁻³, hall mobility of carriers in the first metal oxide semiconductor material layer is greater than 20 cm²/(V·s), and a total atomic percentage of indium and zinc in the first metal oxide semiconductor material layer is greater than 40%;

forming a first metal oxide semiconductor layer 410 and a second metal oxide semiconductor layer 420 by patterning the first metal oxide semiconductor material layer and the second metal oxide semiconductor material layer.

The method for preparing the metal oxide thin film transistor provided by the present disclosure may be used to prepare any one of the metal oxide thin film transistors described in the above embodiments of the metal oxide thin film transistor, and its specific details, principles and beneficial effects have been described in detail in the above embodiments of the metal oxide thin film transistor, or can be reasonably derived from the above description of the above embodiments of the metal oxide thin film transistor, which will not be repeated herein.

Optionally, forming the gate insulating layer 300 includes:

forming a first silicon oxide layer 310, the first silicon oxide layer 310 is provided on a surface of the first metal oxide semiconductor layer 410 away from the second metal oxide semiconductor layer 420; when forming the first silicon oxide layer 310, a ratio of a nitrous oxide flow rate to a silane flow rate is (50 to 70): 1, and a temperature is within a range of 150 to 200° C.

Optionally, the method for preparing the metal oxide thin film transistor further includes:

forming a second silicon oxide layer 621. The second silicon oxide layer 621 and the active layer 400 are located on a same side of the backplane 100, and the second silicon oxide layer 621 is located on a side of the second metal oxide semiconductor layer 420 away from the first metal oxide semiconductor layer 410; when forming the second silicon oxide layer 621, a ratio of a nitrous oxide flow rate to a silane flow rate is (60 to 80): 1, and a temperature is within a range of 200 to 250° C.

It may be understood that when forming the gate 200, the gate insulating layer 300, the active layer 400 and the source-drain metal layer 500 that are stacked, according to the different preparation sequence of each film layer, a top-gate type metal oxide thin film transistor or a bottom-gate type metal oxide thin film transistor may be prepared.

For example, in an embodiment of the present disclosure, a bottom gate type metal oxide thin film transistor may be prepared by forming a gate 200, a gate insulating layer 300, an active layer 400, and a source-drain metal layer 500 on a side of a backplane 100 in sequence. Exemplarily, an exemplary bottom-gate type metal oxide thin film transistor may be prepared by referring to the method shown in steps S110 to S170.

For another example, in another embodiment of the present disclosure, a top-gate type metal oxide thin film transistor may be prepared by forming an active layer 400, a gate insulating layer 300, a gate 200 and a source-drain metal layer 500 on a side of a backplane 100 in sequence. Exemplarily, an exemplary top-gate type metal oxide thin film transistor may be prepared by referring to the methods shown in steps S210 to S260.

It should be understood that the present disclosure does not limit its application to the detailed structure and arrangement of components set forth in this specification. The present disclosure may have other embodiments, and may be implemented and executed in various ways. The aforementioned variations and modifications fall within the scope of the disclosure. It should be understood that the disclosure disclosed and defined in this specification extends to all alternative combinations of two or more individual features mentioned or apparent in the specification and/or drawings. All of these different combinations constitute various alternative aspects of the present disclosure. The embodiments described in this specification illustrate the best mode known for carrying out the present disclosure, and will enable those skilled in the art to utilize the present disclosure.

1. A metal oxide thin film transistor, comprising a gate, a gate insulating layer, an active layer and a source-drain metal layer stacked on a side of a backplane, wherein the active layer and the gate are provided on both sides of the gate insulating layer, respectively, and the source-drain metal layer is provided on a side of the active layer away from the backplane, the active layer comprises:
a first metal oxide semiconductor layer provided on a side of the gate insulating layer away from the gate; wherein a carrier concentration in the first metal oxide semiconductor layer is greater than 1×10²⁰ cm⁻³, hall mobility of carriers in the first metal oxide semiconductor layer is greater than 20 cm²/(V·s), and a total atomic percentage of indium and zinc in the first metal oxide semiconductor layer is greater than 40%;
a second metal oxide semiconductor layer provided on a surface of the first metal oxide semiconductor layer away from the gate.

2. The metal oxide thin film transistor according to claim 1, wherein the carrier concentration in the first metal oxide semiconductor layer is equal to or less than 1×10²¹ cm⁻³, and the hall mobility of the carriers in the first metal oxide semiconductor layer is within a range of 25 cm²/(V·s) to 50 cm²/(V·s).

3. The metal oxide thin film transistor according to claim 1, wherein a band gap of material of the second metal oxide semiconductor layer is equal to or greater than 3.0 eV.

4. The metal oxide thin film transistor according to claim 1, wherein a band gap of material of the second metal oxide semiconductor layer is equal to or less than 3.2 eV.

5. The metal oxide thin film transistor according to claim 1, wherein a conduction band of material of the second metal oxide semiconductor layer is greater than a conduction band of material of the first metal oxide semiconductor layer, and a Fermi energy level of the material of the second metal oxide semiconductor layer is greater than a Fermi energy level of the material of the first metal oxide semiconductor layer.

6. The metal oxide thin film transistor according to claim 1, wherein a band gap of material of the second metal oxide semiconductor layer is greater than a band gap of material of the first metal oxide semiconductor layer, the carrier concentration in the first metal oxide semiconductor layer is greater than a carrier concentration in the second metal oxide semiconductor layer; the hall mobility of the carriers in the first metal oxide semiconductor layer is greater than hall mobility of carriers in the second metal oxide semiconductor layer.

7. The metal oxide thin film transistor according to claim 1, wherein a thickness of the first metal oxide semiconductor layer is within a range of 100 to 300 angstroms; a thickness of the second metal oxide semiconductor layer is within a range of 200 to 400 angstroms.

8. The metal oxide thin film transistor according to claim 1, wherein material of the first metal oxide semiconductor layer is one of indium tin oxide, indium zinc oxide, indium gallium tin oxide, indium tin zinc oxide, indium gallium zinc tin oxide, first indium gallium zinc oxide, second indium gallium zinc oxide and third indium gallium zinc oxide;
wherein in the first indium gallium zinc oxide, in terms of an atomic molar number, indium:gallium:zinc=1:(0.7 to 1.3):(0.7 to 1.3); in the second indium gallium zinc oxide, in terms of an atomic molar number, indium:gallium:zinc=4:(1.7 to 2.3):(2.7 to 3.3); in the third indium gallium zinc oxide, in terms of an atomic molar number, indium:gallium:zinc=4:z(2.7 to 3.3):(1.7 to 2.3).

9. The metal oxide thin film transistor according to claim 1, wherein material of the second metal oxide semiconductor layer is amorphous material, and material of the second metal oxide semiconductor layer is indium gallium zinc oxide or aluminum doped indium gallium zinc oxide.

10. The metal oxide thin film transistor according to claim 1, wherein the gate insulating layer comprises a first silicon oxide layer, and the first metal oxide semiconductor layer is provided on a surface of the first silicon oxide layer away from the gate;
the metal oxide thin film transistor further comprises a second silicon oxide layer provided on a side of the second metal oxide semiconductor layer away from the gate insulating layer;
an atomic percentage of oxygen in the second silicon oxide layer is greater than an atomic percentage of oxygen in the first silicon oxide layer.

11. A method for preparing a metal oxide thin film transistor, comprising: forming a gate, a gate insulating layer, an active layer and a source-drain metal layer stacked on a side of a backplane, wherein the active layer and the gate are provided on both sides of the gate insulating layer, respectively, and the source-drain metal layer is provided on a side of the active layer away from the backplane; wherein forming the active layer on the side of the backplane comprises:
forming a first metal oxide semiconductor material layer and a second metal oxide semiconductor material layer on the side of the backplane, providing the first metal oxide semiconductor material layer on a side of the gate insulating layer away from the gate, and providing the second metal oxide semiconductor material layer on a surface of the first metal oxide semiconductor material layer away from the gate; wherein a carrier concentration in the first metal oxide semiconductor material layer is greater than 1×10²⁰ cm⁻³, hall mobility of carriers in the first metal oxide semiconductor material layer is greater than 20 cm²/(V·s), and a total atomic percentage of indium and zinc in the first metal oxide semiconductor material layer is greater than 40%;
forming a first metal oxide semiconductor layer and a second metal oxide semiconductor layer by patterning the first metal oxide semiconductor material layer and the second metal oxide semiconductor material layer.

12. The method for preparing the metal oxide thin film transistor according to claim 11, wherein forming the gate insulating layer comprises:
forming a first silicon oxide layer, wherein the first silicon oxide layer is provided on a surface of the first metal oxide semiconductor layer away from the second metal oxide semiconductor layer;
wherein when forming the first silicon oxide layer, a ratio of a nitrous oxide flow rate to a silane flow rate is (50 to 70): 1, and a temperature is within a range of 150 to 200° C.

13. The method for preparing the metal oxide thin film transistor according to claim 11, further comprising
forming a second silicon oxide layer, wherein the second silicon oxide layer and the active layer are located on a same side of the backplane, and the second silicon oxide layer is located on a side of the second metal oxide semiconductor layer away from the first metal oxide semiconductor layer;
wherein when forming the second silicon oxide layer, a ratio of a nitrous oxide flow rate to a silane flow rate is (60 to 80): 1, and a temperature is within a range of 200 to 250° C.

14. An array substrate comprising a metal oxide thin film transistor; wherein the metal oxide thin film transistor comprises a gate, a gate insulating layer, an active layer and a source-drain metal layer stacked on a side of a backplane, wherein the active layer and the gate are provided on both sides of the gate insulating layer, respectively, and the source-drain metal layer is provided on a side of the active layer away from the backplane, the active layer comprises:
a first metal oxide semiconductor layer provided on a side of the gate insulating layer away from the gate; wherein a carrier concentration in the first metal oxide semiconductor layer is greater than 1×10²⁰ cm⁻³, hall mobility of carriers in the first metal oxide semiconductor layer is greater than 20 cm²/(V·s), and a total atomic percentage of indium and zinc in the first metal oxide semiconductor layer is greater than 40%;
a second metal oxide semiconductor layer provided on a surface of the first metal oxide semiconductor layer away from the gate.

15. The array substrate according to claim 14, wherein the carrier concentration in the first metal oxide semiconductor layer is equal to or less than 1×10²⁰ cm⁻³, and the hall mobility of the carriers in the first metal oxide semiconductor layer is within a range of 25 cm²/(V·s) to 50 cm²/(V·s).

16. The array substrate according to claim 14, wherein a band gap of material of the second metal oxide semiconductor layer is equal to or greater than 3.0 eV.

17. The array substrate according to claim 14, wherein a band gap of material of the second metal oxide semiconductor layer is equal to or less than 3.2 eV.

18. The array substrate according to claim 14, wherein a conduction band of material of the second metal oxide semiconductor layer is greater than a conduction band of material of the first metal oxide semiconductor layer, and a Fermi energy level of the material of the second metal oxide semiconductor layer is greater than a Fermi energy level of the material of the first metal oxide semiconductor layer.

19. The array substrate according to claim 14, wherein a band gap of material of the second metal oxide semiconductor layer is greater than a band gap of material of the first metal oxide semiconductor layer, the carrier concentration in the first metal oxide semiconductor layer is greater than a carrier concentration in the second metal oxide semiconductor layer; the hall mobility of the carriers in the first metal oxide semiconductor layer is greater than hall mobility of carriers in the second metal oxide semiconductor layer.

20. The array substrate according to claim 14, wherein a thickness of the first metal oxide semiconductor layer is within a range of 100 to 300 angstroms; a thickness of the second metal oxide semiconductor layer is within a range of 200 to 400 angstroms.
